(19) United States
(12) Patent Application Publication
(10) Pub. No.: US 2016/0230044 A1
(43) Pub. Date: Aug. 11, 2016

(54) Modified Conformal Coatings With Decreased Sulfur Solubility

(71) Applicant: International Business Machines Corporation, Armonk, NY (US)

(72) Inventors: Dylan J. Boday, Tucson, AZ (US); Joseph Kuczynski, North Port, FL (US); Jason T. Wertz, Pleasant Valley, NY (US); Jing Zhang, Poughkeesie, NY (US)

(21) Appl. No.: 14/618,208

(22) Filed: Feb. 10, 2015

(51) Int. Cl. C09D 183/08; C23C 16/505

(52) U.S. Cl. CPC C09D 183/08; C23C 16/505

(57) ABSTRACT

Embodiments of the disclosure generally provide coating compositions and methods comprising poly(siloxane) (silicone) polymers and their modification. Plasma fluorine addition (fluorination) improves the barrier properties of poly(siloxane) coatings by decreasing the corrosive permeant solubility and by slowing permeant diffusion through the coating. Surface fluorinated poly(siloxane) coatings are thus more effective barriers to sulfur and sulfurous gas corrosion, and thereby enhance the lifetime of electronic components and associated circuitry.

### BACKGROUND

The present disclosure generally relates to compositions and methods for improved poly(siloxane) conformal barrier coatings for use in the field of electronics.

Conformal coatings are used to protect printed circuit boards and electronic components from corrosion caused by moisture and other contaminants, which can cause short circuits from dendrite growth, electromigration of metal between conductors, and other ill effects. Conformal coatings also protect from organic solvents, abrasion, vibration, and help maintain the dielectric or insulation resistance of the circuit board.

Conformal coatings are typically polymeric materials applied in thin layers (a few mils or a fraction of a mm) onto printed circuits and other electronic substrates. Conformal coatings are traditionally applied by dipping, spraying or simple flow coating, and increasingly by select coating or robotic dispensing. In some cases, the coating may be vapor deposited from a precursor. Some examples of polymeric materials used as conformal coatings are: acrylics, epoxies, urethanes, parylene and poly(siloxanes) (silicones).

The poly(siloxane) family of materials, including poly(dimethylsiloxane) (PDMS) and its copolymers, are of particular utility as conformal coatings for circuit boards and electronic components because of their thermal resistance, flexibility, vibration damping properties, good adhesion to circuit boards, and water repellency. Poly(siloxane) conformal coatings have found widespread application in the protection of electronic circuits and components used in industrial automation and in the automotive and aerospace industries where high temperatures, vibration, and humidity may be found.

However, poly(siloxanes) such as PDMS and it's copolymers, have limited barrier properties, which may limit their ability to protect electronics from corrosive contaminants. This is because of the large free volume inherent in silicone polymers which may allow the permeation of gaseous molecules through the polymer. The high free volume found in the silicones is a result of long intra-molecular bonds, flexible (—Si—O—Si—) backbones and weak intermolecular forces. To overcome this inherent weakness, protective silicone coatings are applied at thicknesses that are much greater than other conformal coatings, and may approach 200 micrometers, about 10 times thicker than other conformal coatings. The thick poly(siloxane) coating thus provides a longer path for the diffusion of corrosive gas molecules, and by that virtue alone may meet the specification for the particular application. Unfortunately, thicker conformal coatings increase material costs and application throughput, so it would be an advantage to apply a thinner conformal silicone coating with improved bather properties.

Because of the current limitations of poly(siloxane) coatings, there is a need for new poly(siloxane) coatings that are thinner and provide improved resistance to permeation of corrosive contaminants for the protection of electronic circuits and components.

### BRIEF DESCRIPTION OF THE SEVERAL VIEWS OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1A is a flowchart depicting steps associated with a method 100 used to modify a conformal coating according to some embodiments of the disclosure.

FIG. 1B is a cross-sectional drawing showing a circuit board component that is covered by a conformal coating, according to some embodiments of the disclosure.

### DETAILED DESCRIPTION

The present disclosure provides coating compositions and methods comprising fluorine and poly(siloxanes). The poly(siloxane) coatings are surface modified by plasma fluorine treatment, and the coatings exhibit improved bather properties over non-fluorine-treated poly(siloxanes). The coatings are useful for the protection of electronic circuits and components from corrosion by sulfur, sulfurous gases, and other corrosive contaminants including chlorine, hydrogen chloride, ammonia, ozone, and nitrogen oxides.

Poly(siloxanes) are inorganic-organic polymers that have an inorganic silicon-oxygen backbone chain (—Si—O—Si—) with organic side groups attached to the four-coordinate silicon atoms. Poly(siloxanes) may be represented by the chemical formula [R₂SiO]ₙ, where R is an organic group. The organic group may be aliphatic, aromatic, or both, and may further comprise other atoms and/or chemical functionalities that are inorganic. The functionality attached to the silicon atoms may be charged or neutral. Alternatively, and without restricting this disclosure, one or both of the R groups may be designated R′, and may further represent other chemical moieties, including, but not restricted to the halogens, hydrogen, and other main group elements. Generally, by varying the (—Si—O—Si—) chain lengths, side groups, molecular weight, branching, and degree of cross-linking, poly(siloxanes) can be synthesized with a wide variety of properties and compositions, and they may vary in consistency from liquids to gels, and from rubbers to hard plastics.

The coatings described herein have improved barrier properties through modification of solution and diffusion properties. Permeation through a barrier or membrane material, such as a poly(siloxane) coating, proceeds by 1), absorption of the permeant into the material, a function of the solubility of the permeant in the material, which depends on the chemical affinity and/or repulsion of the materials to one another; 2), diffusion of the permeant through the material; and 3), desorption of the permeant from the other side. Diffusion typically involves a tortuous path for the permeant to follow, so generally a denser or more crystalline material will slow the permeants progress. In some cases, fillers, such as platelet silica, may be added to a material as a further barrier to diffusion. Diffusion, and solution to an extent, are processes driven by a concentration difference or gradient (entropy), where the molecules permeate from a high concentration area of the material to a low concentration area, and continuing until the concentration equalizes.

By the processes described above, gases permeate poly(siloxane) polymers by a solubility/diffusion mechanism, where the rate of gas permeation is directly proportional to the product of solubility of the gas, and the rate of diffusion of the dissolved gas (P=S·D). The permeability coefficient (P) is a parameter defined as the transport flux of a gas (rate of gas permeation per unit area), per unit driving force, per unit membrane thickness. Temperature also affects permeability in poly(siloxane) polymers that are used in elevated temperature applications. The Arrhenius equation, P=Pₒe^{(-E/RT)}, where P is the permeability, Pₒ is the permeability constant, E is the activation energy, R is the gas constant, and T is the temperature, relates temperature to permeability. For high temperature applications, where poly(siloxane) conformal coatings find most utility (65° C. to 200° C.), it is observed that gases will permeate through the material at a higher rate, thus necessitating a thicker coating. Permeation rates of gases and permeation coefficients may be measured by a number of methods including coulometric (ASTM D 3895), manometric (ASTM D 1434), and carrier gas (ISO 15105-1). Instruments that measure permeation, and permeation testing services are provided by companies such as Mocon Inc., of Minneapolis, Minn., USA.

The coatings described herein may be thinner than non-modified conformal silicone coatings, due to improved barrier properties. The solubility and diffusion factors governing permeation are adjusted to enhance the barrier properties of poly(siloxane) coatings by modifying the coating chemical polarity, density, and cross-link density. This is achieved by modifying the R groups of the general poly(siloxane) formula [R₂SiO]ₙ and its copolymers. In some embodiments of the disclosure, improved bather properties are realized by exposure of a silicone conformal coating, for example a coating containing poly(siloxane) polymers, optionally including copolymers, to a plasma containing fluorine radicals and ions, and carbon radicals and ions, to add fluorine atoms and chemical functionality to the surface of the conformal coating. Upon fluorine treatment, the coating may comprise functional groups containing chemically bound fluorine atoms. For example, in some embodiments, the R group is —CF₃, while in other embodiments, the R group may be a larger group, such as phenyl, thus providing a larger steric barrier to corrosive permeants. For the purposes of the disclosure, we do not restrict the identity or chemical make-up of the poly(siloxane) coating, nor the inherent functionality. In summary, the fluorine plasma treated poly(siloxane) coating surface reduces the solubility of polar contaminants in the coating, decreases the wetting of the coating by contaminants, and slows permeant diffusion by physical matrix densification and cross-linking.

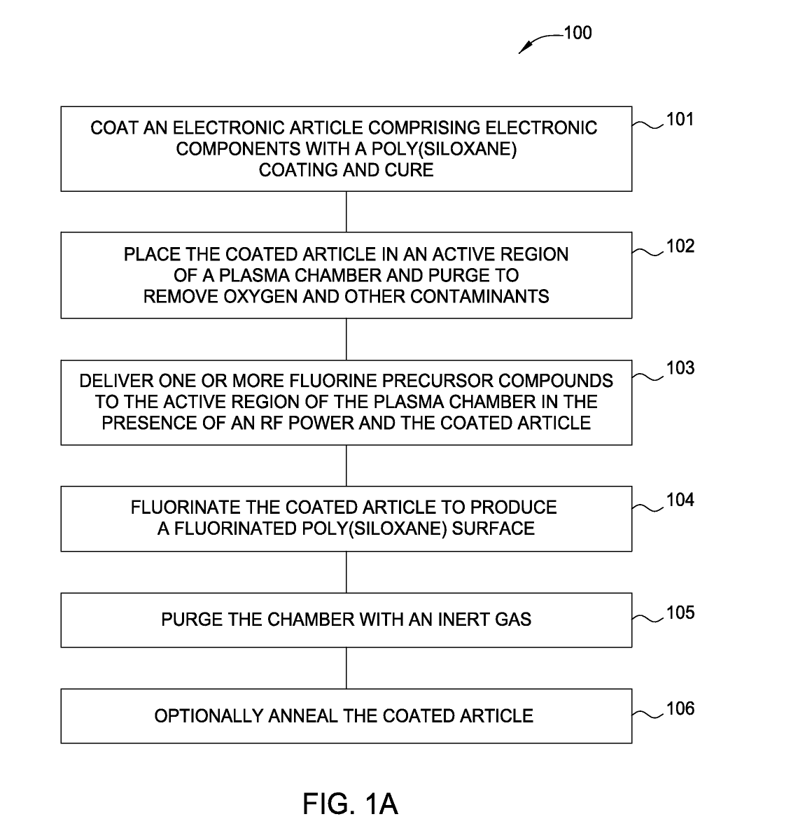

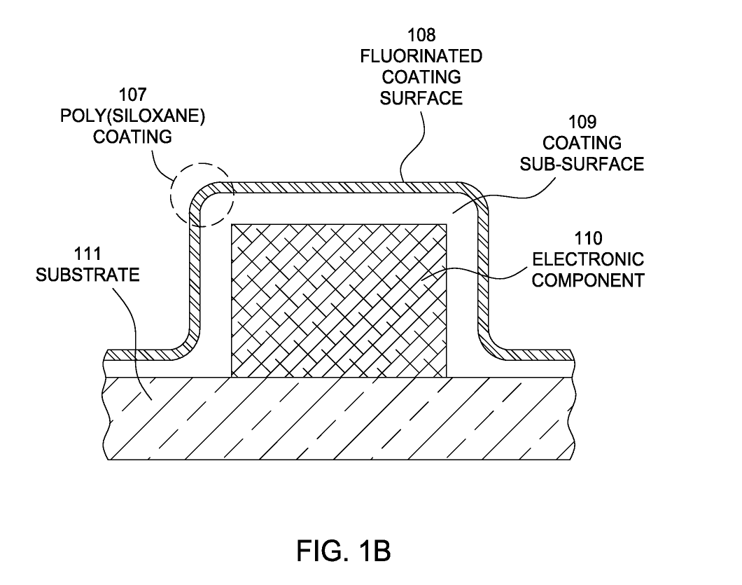

FIG. 1A is a flowchart summarizing a method 100 used to form a fluorine plasma treated poly(siloxane) barrier coating for electronic applications according to some embodiments of the disclosure. At 101, a printed circuit board or other suitable electronic article comprising circuitry and electronic components, such as integrated circuits, transistors, capacitors, resistors, wires and the like, is coated with a suitable poly(siloxane) coating and cured. One example of such a coating is Dow Corning® 1-2620 conformal coating, which may be applied to a printed circuit board or similar by coating methods that are familiar to those skilled in the art, including: spray, brush, flow, dip, and automated pattern coating. Another coating example is Dow Corning® 3-1953 conformal coating. The above poly(siloxane) conformal coatings are available from Dow Corning Corporation of Midland, Mich., USA.

At 102, the electronic article, with portions of the electronic article optionally masked to prevent any undesired plasma etching, is placed in the active region of a plasma chamber. The chamber may be exposed to a vacuum to remove oxygen and other contaminants. In some embodiments, multiple pump and inert gas back-fill cycles may be used to effectively remove trace quantities of oxygen and moisture. The coating obtained by including oxygen removal from the reaction environment is a low surface energy fluorine containing coating surface that is free of oxides and other polar functionality, such as a silanol group (—SiR₂OH), which otherwise would attract water and other polar contaminants such as sulfur and its oxides.

At 103 and 104, the coated electronic article is contacted with a plasma comprising fluorine ions and/or radicals, such as elemental fluorine and/or fluorinated carbon species, such as —CF₄, as an example. The plasma may include a low power glow discharge formed by radio frequency (RF) excitation of a fluorine containing precursor gas. In 103, the precursor gas, or source of the fluorine containing ions and radicals, is passed through the active region of the plasma chamber and contacts the coated electronic article. The precursor gas may be exposed to the RF excitation in the plasma chamber, or the precursor gas may be exposed to the RF excitation in a second chamber, and the resulting plasma transferred to the plasma chamber. The precursor gas may include fluorine, inorganic sources of fluorine, such as sulfur hexafluoride, aliphatic fluorocarbon gases such as perfluorobutane, or gases from sublimable fluorine containing solids and mixtures thereof. In some embodiments, to avoid degradation of the poly(siloxane) surface by excessive concentrations of fluorine radicals, the fluorine precursor gas may be diluted with an inert gas such as helium, neon, or argon and the like.

The glow discharge is maintained at a sufficiently high energy to form the desired fluorine containing ions or radicals while at the same time avoiding high temperatures which would degrade the surface of the polymer being treated, or any electronic components. The plasma may be produced in-situ or remotely by any conventionally available means such as RF excitation, microwave excitation or with electrodes. Suitable plasmas may be formed with a radio frequency discharge operating between about 10 KHz and about 20 MHz and between about 10 and about 500 watts or with a microwave discharge operating between about 10⁴ and about 10⁶ MHz and between about 10 and about 500 watts. The power ranges recited here are approximately sized for a 15 cm diameter reactor and may be increased for a larger reactor. We further note that the conditions for plasma fluorination may be adjusted by those skilled in the art to produce a “soft” plasma or conditions that will not degrade or damage the poly(siloxane) coating, and thus will provide a fluorine treated surface that is mostly free of defects, such as dangling bonds or unsatisfied valences which may lead to hydrolysis and environmental attack.

In other embodiments, a mixture of precursors may be used to perform a fluorine treatment. In one example, a sulfur hexafluoride/trifluoromethane/helium mixture (SF₆/CHF₃/He) is introduced into the active region as a combination of between about 1 and about 5 sccm of SF₆, of between about 1 and about 20 sccm of a fluorocarbon such as CHF₃, and between about 40 and about 50 sccm of argon, for a total chamber pressure between about 1 and 30 mTorr. The power applied to the fluorination chemistry is between about 10 and about 500 watts of inductive source power (at 12.56 MHz) via an inductively coupled antenna and between about 10 and about 500 watts (at 13.56 MHz) of cathode bias power applied via a cathode electrode within an article support pedestal. In further embodiments, a Faraday Cage may be used to focus the plasma, prevent ion damage, and produce more uniform treatment of the poly(siloxane) coating.

The temperature at which plasma fluorination is performed is less than that which causes degradation to the coating and electronic article, while permitting substantially complete replacement of the hydrogen atoms on the substrate with fluorine from the plasma. An acceptable temperature range may be between about 10° C. and about 100° C., such as 25° C. and about 50° C., and may be adjusted by a temperature controlled chuck or pedestal upon which the electronic article is placed in the active region. Those skilled in the art will accordingly adjust the temperature, time of exposure, total pressure, and concentration of the fluorine containing species to prevent damage to the coating.

FIG. 1B, is a cross-sectional drawing of an electronic component 110 on a printed circuit board 111, with a poly(siloxane) coating 107 that further comprises a fluorine containing surface 108 and a coating sub-surface 109, that may not contain fluorine, or may contain a reduced fluorine content. As a result of operations 103 and 104, the coating 107 may have a low energy fluorine containing surface 108, with surface energies from between about 5 mJ/m² and about 15 mJ/m², in contrast to non-fluorinated poly(siloxane), such as PDMS, with a surface energy of about 22 mJ/m². Surface 108 may repel polar gaseous molecules and their condensates, such as water, sulfur, sulfur oxides, hydrogen sulfide, chlorine, hydrogen chloride, ammonia, ozone, and nitrogen oxides. Those skilled in the art may measure surface energy and contact angle respectively using a calibrated dyne pen, microscope and a goniometer instrument. The lower surface energy found in fluorine containing surface 108 may be reflected by an increase in water droplet contact angle. In some embodiments, the contact angle for fluorine containing surface 108 is 1.5 times or more greater than non-fluorinated PDMS (114°). The practitioner may use the sessile drop method for measurement of contact angle, using a DataPhysics OCA 20 apparatus (DataPhysics, Germany).

As shown in FIG. 1B, the articles and products of this method yield a top surface 108 of the poly(siloxane) coating 107 that may include chemically bound fluorine atoms and fluorinated functional groups, at depths between about 1 nm and about 100 nm, thereby reducing the solubility and permeation of polar contaminant gases in and through the coating 107, which in-turn protects component 110 from corrosion. In other embodiments, surface 108 contains chemically bound fluorine between about 1 atomic % and about 50 atomic % based on polymer, wherein the fluorine content depth profile in fluorine containing surface 108 may range from the air interfacial surface to a depth of about 100 nm, and/or such that the coating contains chemically bound fluorine from the air interfacial surface to a depth that is 50% of the coating 107 thickness. Common methods used by those skilled in the art to measure fluorine content in a polymer include x-ray photoelectron spectroscopy (XPS) and time of flight secondary ion spectroscopy (TOF-SIMS).

Another unexpected benefit of the fluorine plasma treatment (fluorination) of a poly(siloxane) coating is a fluorine containing surface 108 that is denser and harder than a non-fluorinated coating. Ion bombardment in the plasma fluorination process causes surface molecular rearrangement and cross-linking, thus creating a further physical barrier to diffusion of gases and other corrosive contaminants in the coating. For example, in some embodiments, a Young's modulus of fluorine containing surface 108 may be increased by 1.5 times or more (≧681 KPa), relative to non-plasma fluorinated PDMS (360 to 870 KPa). In further embodiments, the coating hardness and modulus may be adjusted by the time of plasma exposure, gaseous flow rates, power and other parameters. Those skilled in the art may obtain hardness and modulus values by the nanoindentation technique, using equipment such as the FISCHERSCOPE® HM2000 (Fischer Technology, Inc., Windsor, Conn., USA).

Returning back to method 100, operation 105 involves the purging of the chamber to remove fluorine and other noxious gases prior to removal of the electronic article from the chamber. Operation 106 is an optional annealing step that may be used to eliminate contaminants, such as oxygen, or to further densify and rearrange the molecular structure of the coating 107. As mentioned above, a fluorine containing low surface energy surface 108 is obtained when oxygen and moisture are excluded. In some embodiments, operation 106 involves annealing the substrate between about 50° C. and about 150° C., in an inert gas environment or a reducing gas environment. The anneal treatment may relieve stresses, heal defects, and close pinholes in the coating 107 and/or coating-component interface at 110. Additionally, annealing may be used to reduce oxides and dangling bonds in surface 108. Further benefits of annealing may include increased adhesion of the coating 107 to components such as 110, and the substrate 111.

While the foregoing is directed to embodiments of the present disclosure, other and further embodiments of the disclosure may be devised without departing from the basic scope thereof, and the scope thereof is determined by the claims that follow.

What is claimed is:

1. An electronic article, comprising:
a substrate comprising electronic components; and
a fluorine containing poly(siloxane) conformal coating disposed over the substrate.

2. The electronic article of claim 1, wherein the coating comprises a surface thickness and a sub-surface thickness.

3. The electronic article of claim 2, wherein the surface thickness comprises chemically bound fluorine.

4. The electronic article of claim 2, wherein the sub-surface thickness comprises a poly(siloxane) polymer that does not contain fluorine.

5. The electronic article of claim 2, wherein a total thickness of the fluorine containing poly(siloxane) conformal coating is 50% of the total coating thickness or less.

6. The electronic article of claim 3, wherein a fluorine content of the surface thickness ranges from 1 atomic percent to 50 atomic percent based on the polymer coating.

7. The electronic article of claim 3, wherein the surface comprises cross-links.

8. The electronic article of claim 3, wherein the surface energy of the fluorine containing surface thickness is 22 mJ/cm² or lower than the non-fluorine containing sub-surface thickness.

9. The electronic article of claim 3, wherein the surface hardness is at least 1.25 greater than the sub-surface.

10. The electronic article of claim 3, wherein the surface modulus is at least 1.25 greater than the sub-surface.

11. The electronic article of claim 3, wherein the solubility coefficient of sulfur and sulfur chemical compounds in the coating surface is less than 75 percent of the sub-surface.

12. The electronic article of claim 3, wherein the permeation coefficient of sulfur and sulfur chemical compounds in the coating surface is less than 75 percent of the sub-surface.

13. The electronic article of claim 3, wherein the permeation rate of sulfur and sulfur chemical compounds in the coating surface is less than 75 percent of the sub-surface.

14. The electronic article of claim 2, wherein the surface comprises fluorine containing poly(dimethylsiloxane) polymers.

15. The electronic article of claim 2, wherein the sub-surface comprises poly(dimethylsiloxane) polymers.

16. The electronic article of claim 2, wherein the surface comprises fluorine containing poly(dimethylsiloxane) polymers and phenyl groups.

17. A method of producing an electronic article, comprising:
coating a surface of a substrate comprising electronic components with a poly(siloxane) containing polymer;
placing the coated substrate in a processing region of a plasma chamber;
purging the chamber so that it is that is free of oxygen and moisture and other contaminants;
exposing a fluorine containing compound to RF power to form an activated fluorine containing gas mixture;
exposing the coated substrate to the activated fluorine containing gas mixture in a processing region of a plasma chamber to form a fluorine treated substrate; and
purging the chamber with an inert gas.

18. The method of claim 17, further comprising annealing the fluorine treated substrate between about 50° C. and about 150° C. to reduce unsatisfied atomic valence and remove surface oxides.

19. The method of claim 17, wherein the coating comprises poly(dimethylsiloxane) polymers.

20. The method of claim 19, wherein the coating of the fluorine treated substrate comprises a plasma cross-linked fluorinated surface and a non-fluorinated sub-surface.
